(19) United States
(12) Patent Application Publication
(10) Pub. No.: US 2015/0108873 A1
(43) Pub. Date: Apr. 23, 2015

(54) Sound Transducer Arrangement

(71) Applicant: Robert Bosch GmbH, Stuttgart (DE)

(72) Inventor: Andre Gerlach, Leonberg-Hiefingen (DE)

(73) Assignee: Robert Bosch GmbH, Stuttgart (DE)

(21) Appl. No.: 14/379,071

(22) PCT Filed: Feb. 7, 2013
(86) PCT No.: PCT/EP2013/052392

§ 371 Date: Aug. 15, 2014

(30) Foreign Application Priority Data
Feb. 16, 2012 (DE) 10 2012 202 422.0

(51) Int. Cl. B06B 1/06; H01L 41/053

(52) U.S. Cl. CPC B06B 1/0622; H01L 41/0533
USPC 310/334

(57) ABSTRACT

A sound transducer system is provided having a piezoelectrically active electret material between a first and a second electrode structure. The electret material is applied on the first electrode structure, so that the first electrode structure is completely covered with the electret material. The second electrode structure is situated on or above the electret material, so that the electret material is situated between the first and second electrode structure. The first electrode structure is configured from a plurality of electrode elements that are addressable independently of one another. The electrode elements thus define the individual sound transducer elements, which together form a sound transducer system, also designated an array. The first electrode structure is configured on a surface of a multilayer circuit bearer.

### FIELD OF THE INVENTION

The present invention relates to a sound transducer system that can be used in particular for sound-based environmental detection, and to a sound wave-based sensor containing the sound transducer system. Under consideration here are array systems made up of at least two sound transducers. In such systems, the distance from one another of two or more individual transducers is typically less than half the sound wavelength in air. In comparison to single-element transducers, an array system offers expanded possibilities for signal processing, and can thus be used particularly advantageously in complex environments, with the complex sound fields resulting therefrom. The individual transducer elements can be operated separately as sound emitters and as sound receivers, or alternatively as both emitters and receivers. In addition, the present invention relates to a sound wave-based sensor for environmental detection, in particular an ultrasound sensor for automotive applications or for applications in robotics or for mobile working machines, having a sound transducer system constructed according to the present invention.

### BACKGROUND INFORMATION

Sound transducers based on the electret principle are discussed in the literature. For example, in WO 1008/135004 A1 an ultrasound transducer array is discussed for applications in gaseous media, including a layer of a piezoelectrically active cellular electret material between two electrode structures. Here, the transducer elements are primarily determined in their size by the dimensions of the electrode structure.

In order to form arrays, it is necessary to form a plurality of sound transducer elements each having two electrodes, each limiting the effective range of a respective element. The electrodes must be connected to downstream electronic components (e.g. amplifiers or filters). The greater the number of required elements, the more difficult is the connection to downstream electronic components. For example, problems occur above all if the electrode elements are not configured in a line (line array), but are distributed two-dimensionally (2-D array). In this case, in conventional configurations the printed conductors must be routed between the individual electrode elements. These printed conductors reduce the available surface for the use as an electrode element. Moreover, they represent additional capacitances that have to be recharged by the sound transducer elements in parallel to the downstream electronic components. If a surface of the electret material is completely metalized and used as a ground electrode, then in this case the printed conductors also form parasitic sound transducer elements that are not desirable at these locations and that disturb the array signal processing.

### SUMMARY OF THE INVENTION

The sound transducer technology described in the present invention is based on a piezoactive electret material that carries out the conversion between a mechanical stress caused by sound pressure and an electrical field.

An electret material is understood to be an electrically insulating material that contains quasi-permanently stored electrical charges or quasi-permanently oriented electrical dipoles, and thus produces a quasi-permanent electrical field in its surrounding environment or in its interior. Piezoelectrically active electret materials are often configured as so-called ferroelectrets, and have a cellular or foam-like structure. Sound transducers based on electrets have properties for sound production and sound reception in fluids (gases, liquids) that are particularly advantageous in comparison with other transducer technologies such as mechanical resonance transducers, piezocomposite transducers, electrostatic transducers, or MEMS transducers, in particular with regard to electroacoustic reception sensitivity.

According to the present invention, a sound transducer system is proposed including a piezoelectrically active electret material between a first and a second electrode structure. The electret material is applied onto the first electrode structure, in particular in such a way that the first electrode structure is completely covered with the electret material. The electret material forms a piezoelectric layer. The second electrode structure is situated on or above the electret material, so that the electret material is situated between the first and the second electrode structure. The first electrode structure is configured from a plurality of electrode elements that can be addressed independently of one another. In this way, the electrode elements define the individual sound transducer elements, which together form a sound transducer configuration, also referred to as an array. Here, according to the present invention the first electrode structure is configured on a surface of a multilayer circuit bearer.

Through the electrode elements of the first electrode structure in connection with the second electrode structure situated on the opposite side of the layer of the piezoelectrically active electret material, in a known manner local thickness vibrations of the layer or of pores of the layer can be produced or detected. In particular, the frequencies of these vibrations can be in the ultrasound range. The excitation of the thickness vibrations takes place in a known manner through suitable voltage signals that are applied between the respective electrode elements and the counter-electrode of the second electrode structure. These voltage signals produce local thickness vibrations of the piezoelectrically active electret material, which in turn bring about the radiation of sound waves. When there are incident sound waves, the piezoelectrically active electret material is excited by the sound waves to execute thickness vibrations that in turn produce corresponding voltage signals at the respective electrode elements.

The first electrode structure may be formed from the uppermost layer of the multilayer circuit bearer, or is applied onto a surface of the multilayer circuit bearer. Following this, the electret material is applied onto the first electrode structure, for example by gluing. Alternatively, it is also possible to apply the electret material using a printing method, for example screen printing. It is also possible first to apply the first electrode structure onto a surface of the electret material and then to connect the electret material to the multilayer circuit bearer, for example by gluing.

The design according to the present invention of the sound transducer system yields the advantage that the different layers of the multilayer circuit bearer can be used for the interconnection of the individual electrode elements. The multilayer circuit bearer can for example be realized in a conventional manner as a multilayer circuit board having a plurality of circuit levels. The uppermost layer can advantageously be used to form the first electrode structure. The electrode elements can be connected to downstream electronic components via various wiring levels. For this purpose, so-called vias can be used. The surface available for forming the electrode elements is enlarged in this way, because no additional surface for printed conductors has to be provided on the surface of the circuit bearer, or of the first electrode structure. In addition, the respective size and shape of the electrode elements and the routing of the printed conductors can be defined independently of one another.

A further advantageous function of the multilayer circuit bearer is the provision of a bearer layer for the mechanical stabilization of the sound transducer system. Circuit boards, in particular composite systems for example having fibers as filler material, may be used as circuit bearers. In particular, the filler material of the composite system is selected such that when there is mechanical action from outside on the surface on which the sound transducer system is formed, the circuit board is flexible. In this way, a part of the mechanical stress is absorbed not in the electret material but rather by the circuit board, and damage to the sensitive electret material is avoided.

The electret material may be configured as a foil, in particular ferroelectret foil. Such foils standardly have a thickness of from 50 to 500 μm, and have a cellular structure. Two or more layers of such foils can also be applied one over the other (stack construction). The thus enlarged layer thickness of the piezoelectrically active electret material achieves a higher sensitivity of the sound transducer system in receive operation, and greater transmit strength in transmit operation. Moreover, it is possible to set a specified frequency for a resonant behavior of the sound transducer system in a targeted manner via the layer thickness.

Advantageous specific embodiments of the present invention are the subject matter of the subclaims. Thus, the second electrode structure may be configured on the piezoelectrically active electret material as a continuous metallization layer, and acts as a ground electrode for the entire sound transducer system. Due to the fact that the printed conductors and the electrode elements are configured on different layers or planes, the spacing of the printed conductors from the second electrode structure is increased. Disturbing capacitances are reduced by the increased spacing.

The second electrode structure may be covered by a protective layer, in particular having a multilayer construction, that protects the sound transducer system from external influences such as moisture, dirt, UV radiation, heat, or mechanical action. This protective layer can also be important for the optical appearance of the system by making it possible to paint it.

In an exemplary embodiment, the multilayer circuit bearer has at least one via. Here, to an electrode element there may be assigned a via that electrically connects the electrode element to a printed conductor that is configured on a particular inner layer of the multilayer circuit bearer. The printed conductor can connect the electrode element to downstream electronic components that for example excite the corresponding transducer element or that further process the signals supplied by the corresponding transducer element.

A plurality of in particular adjacent electrode elements may be connected to printed conductors in such a way that the respective printed conductors are configured on different conductor levels of the multilayer circuit bearer.

On a surface, opposite the first electrode structure, of the multilayer circuit bearer, in an exemplary embodiment of the present invention there can be situated electronic components. These components can for example act as filters or amplifiers for the sound transducer system. This embodiment achieves a particularly compact and space-saving design, because a circuit bearer can be used both as a bearer structure for the first electrode structure and also as a bearer for the downstream electronics of the sound transducer system. Here, particularly advantageous is the short conductor routing, with the associated low parasitic capacitances, resistances, and inductances. The different wiring levels of the circuit bearer can be used both for the addressing of the individual transducer elements and for the formation of the printed conductors for the electronic components.

The sound transducer system according to the present invention can for example be realized in such a way that the electrode elements of the first electrode structure are configured in a line, and the transducer elements thus form a so-called line array.

Also described is an embodiment in which the electrode elements of the first electrode structure are distributed two-dimensionally, and the transducer elements thus form a so-called 2D array. In such a configuration, the advantages due to the formation according to the present invention of the sound transducer system having a multilayer circuit bearer come to bear particularly clearly, because complicated and space-consuming printed conductors between the individual electrode elements of the first electrode structure can be omitted, and instead the various wiring levels of the multilayer circuit bearer can be used.

The multilayer circuit bearer can be realized as a curved circuit board. In this way, the sound transducer system can also be realized having a curve, thus enabling a three-dimensional embodiment. In this way, an embodiment can be realized that is adapted to the shape of the particular application. For example, the curved shape of the sound transducer system can be matched inconspicuously to the outer contour of a vehicle or a machine. This yields expanded possibilities for the selection of installation locations and for the shape of the system. Through an adaptation of the signal processing, due to the three-dimensional distribution of the individual transducer elements it is also possible to achieve an improved adaptation of the signal evaluation to the respective application. Through suitable selection and placement of the electronic components, a curved circuit board can also bear the electronic circuit.

Further advantages and embodiments of the present invention result from the description and the accompanying drawings.

Of course, the features named above and explained below may be used not only in the respectively indicated combination, but also in other combinations, or by themselves, without departing from the scope of the present invention.

### BRIEF DESCRIPTION OF THE DRAWINGS

FIG. 1 schematically shows a section through an exemplary embodiment of a sound transducer system configured according to the present invention.

FIG. 2 schematically shows a top view of an exemplary embodiment of an electrode structure on a surface of a multilayer circuit bearer.

### DETAILED DESCRIPTION

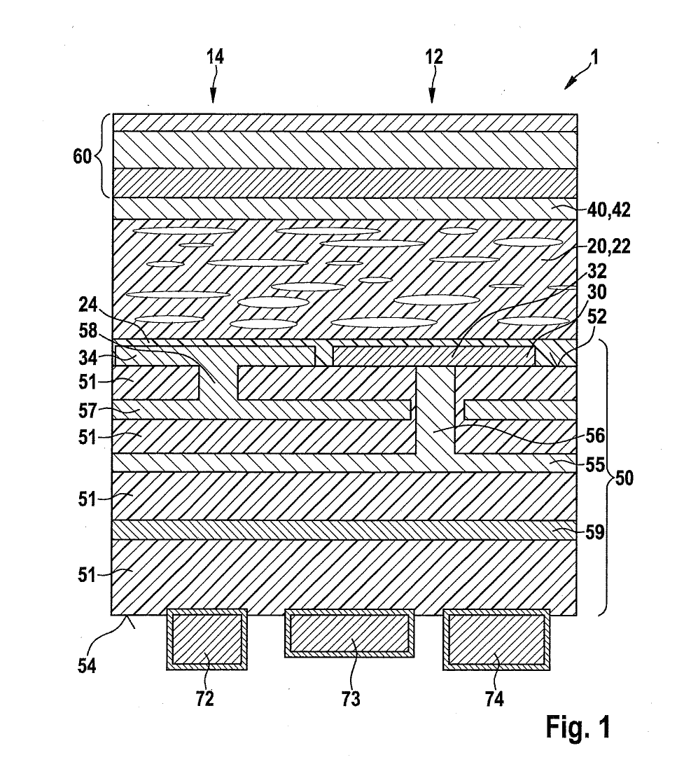

FIG. 1 shows a section through an exemplary embodiment of a sound transducer system according to the present invention. The sound transducer system has a multilayer circuit bearer 50 realized as a multilayer circuit board.

The multilayer circuit bearer has in its interior a plurality of levels of printed conductors 55, 57, separated from one another by an insulating layer 51 made of a composite material, for example a fiber-reinforced plastic.

A first electrode structure 30 is configured on a surface 52 of multilayer circuit bearer 50. In this exemplary embodiment, first electrode structure 30 is formed by corresponding structuring of the uppermost layer of multilayer circuit bearer 50. Two electrode elements 32 and 34 are formed that can be addressed independently of one another, and that form at least a part of first electrode structure 30.

On first electrode structure 30 there is situated a piezoelectrically active electret material 20 that in this exemplary embodiment is configured as ferroelectret foil 22. Ferroelectret foil 22 is fastened on first electrode structure 30 by an insulating adhesive layer 24, and may completely cover first electrode structure 30. Alternatively, an electrically conductive glue can be used; given the use of an electrically conductive glue, only electrode elements 32 and 34 are covered by the glue.

On ferroelectret foil 22 there is situated a second electrode structure 40 that in this exemplary embodiment is configured as continuous metallization layer 42, which is connected to ground potential. The metallization layer can be produced for example by vapor deposition or by sputtering or by a printing method such as screen printing. A voltage signal applied between an electrode element 32 or 34 and metallization layer 42 causes, due to the piezoelectric effect, a change in thickness in piezoelectrically active electret material 20. If sound, or some other mechanical action, acts on electret material 20, the associated change in thickness of piezoelectrically active electret material 20 produces a change in charge, or a voltage, that can be picked off at electrode structure 32, 34, or 40.

Metallization layer 42 is covered with a multilayer protective layer 60 for protection against external influences such as moisture, dirt, UV radiation, heat, or mechanical action. This layer can be made for example of plastic, for example a polymer (e.g. parylene), or from a polyimide (e.g. Kapton), or a composite of different plastics, or a plastic-metal composite.

Accordingly, piezoelectrically active electret material 20 is situated between first electrode structure 30 and second electrode structure 40. Together, first electrode structure 30 on multilayer circuit bearer 50, piezoelectrically active electret material 20, and second electrode structure 40 form a sound transducer system 1. In this example, sound transducer system 1 has two transducer elements 12 and 14, whose respective effective range is determined by the shape and position of electrode element 32 and 34 of first electrode structure 30. Accordingly, first transducer element 12 is formed by electrode element 32, piezoelectrically active electret material 20 in the region above electrode element 32, and second electrode structure 40, and second transducer element 14 is formed by electrode element 34, piezoelectrically active electret material 20 in the region above electrode element 34, and second electrode structure 40.

Through the application of corresponding voltage signals to the various electrode elements 32, 34, in a known manner the piezoelectric effect produces a change in thickness of the electret material above the respective electrode element 32 or 34, and sound waves are radiated. Conversely, incoming sound waves cause a deformation of the electret material, producing voltage signals at electrode elements 32, 34. In this way, sound transducer system 1 can be operated both as a sender and as a receiver. Through the various independently addressable electrode elements 32, 34, during operation of sound transducer system 1 as a receiver a sound field can be detected with high precision and high spatial resolution. In the case of operation of sound transducer system 1 as a transmitter, through superposition of the signals of the various transducer elements 12, 14 a complex sound field can be produced.

Multilayer circuit bearer 50 has vias 56 and 58. Via 56 is assigned to an electrode element 32, and connects electrode element 32 electrically to printed conductor 55. Via 58 is assigned to electrode element 34, and connects electrode element 34 electrically to printed conductor 57. Printed conductors 55 and 57 are configured on different inner conductor levels of multilayer circuit bearer 50. In this way, the respective routing of printed conductors 55 and 57 can be configured independent of one another.

On the surface 54 of multilayer circuit bearer 50, which is situated opposite surface 52 on which first electrode structure 30 is configured, in this example there are situated various electronic components 72, 73, and 74. Components 72, 73, 74 can be for example resistors, capacitors, transistors, or integrated circuits (e.g. operational amplifiers), that form a circuit that can act for example as a filter and/or amplifier for sound transducer system 1. An inner layer 59 of the multilayer circuit bearer may be configured as a continuous metal layer that is at ground potential. In this way, an electromagnetic shielding of the sound transducer system from the circuit including components 72, 73, and 74 is achieved. Electronic components 72, 73, and 74 can for example be contacted via printed conductors that are configured on further inner layers (not shown) of multilayer circuit bearer 50.

Moreover, multilayer circuit bearer 50 acts as a mechanical bearer structure for electrode structures 30 and 40, and for electret material 20, 22. When there is mechanical stress on the sound transducer system, the forces are accommodated mainly by the composite material that forms insulating layers 51 of circuit bearer 50. In this way, damage to ferroelectret foil 22 or to electrode structures 30, 40 is avoided.

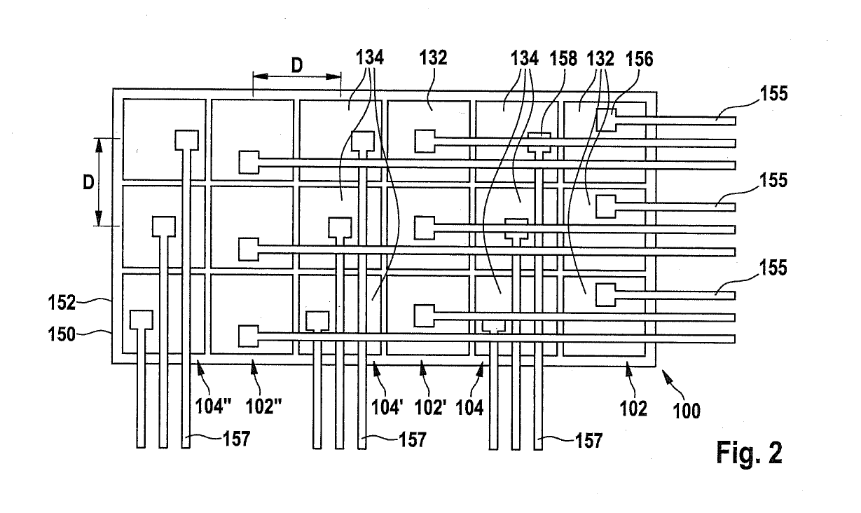

FIG. 2 schematically shows a detailed top view of an exemplary embodiment of a first electrode structure 130 of a sound transducer system according to the present invention. Electrode structure 130 is configured on surface 152 of a multilayer circuit bearer 150. In this example, electrode structure 130 has 18 electrode elements 132, 134, configured in six columns 102, 104, 102′, 104′, 102″, 104″, each having three electrode elements. Accordingly, electrode structure 130 forms a so-called 2D array 100, because electrode elements 132, 134 are distributed two-dimensionally on a surface. In this example, all electrode elements 132, 134 have the same dimensions.

They are essentially square in shape and are configured regularly relative to one another. The dimensions of electrode elements 132, 134 are selected such that spacing D between two adjacent electrode elements 132, 134 is smaller than the half wavelength of a sound wave (in air) at a frequency typical for the application. For example, at a typical operating frequency of 50 kHz, the air sound wavelength is approximately 7 mm. In this case, spacing D, and thus also the edge length of an electrode element, can for example be approximately 3 mm.

Depending on the application of the sound transducer system according to the present invention, configurations are also conceivable in which electrode elements are formed that have different sizes, are shaped differently, and/or are positioned irregularly relative to one another. For example, it is also possible to use rectangular, round, oval, polygonal, or irregularly shaped electrode elements. The electrode elements also do not have to be configured so as to cover the surface. It is possible to leave exposed individual regions of the circuit bearer. One then speaks of an incompletely occupied array configuration.

Each electrode element 132, 134 of electrode structure 130 is assigned a via 156, 158 of multilayer circuit bearer 150. Vias 156, 158 connect electrode elements 132, 134 electrically to printed conductors 155, 157. In this exemplary embodiment, vias 156, 158 are configured in such a way that electrode elements 132 situated in the same column 102 of 2D array 100 are connected by vias 156 to printed conductors 155 in an electrically conductive manner, printed conductors 155 being configured on an inner layer of a multilayer circuit bearer. Electrode elements 134 that are situated in a column 104, adjacent to column 102, of 2D array 100 are connected in an electrically conductive manner to printed conductors 157 by vias 158. Printed conductors 157 are configured on a different inner layer of a multilayer circuit bearer.

Printed conductors 155 and printed conductors 157 accordingly run on different levels, and the respective course of printed conductors 155 and 157 can therefore be selected independently of one another.

From FIG. 2 it can also be seen that no printed conductors need be provided on surface 152 on which electrode structure 130 is configured. All printed conductors 155, 157 run on circuit levels of multilayer circuit bearer 150 that are situated below surface 152. Thus, surface 152 is completely available for configuring electrode structure 130.

A sound transducer system according to the present invention is particularly suitable for sound field-based environmental acquisition. It can be used for example in driver assistance systems such as parking systems, for the support of maneuvering, or to monitor the blind spot of a vehicle. It is also conceivable to use it in robots, for example lawn-mowing robots, vacuum-cleaning robots, transport robots, or also in stationary machines. In addition, a sound transducer system according to the present invention can be used to monitor manufacturing processes and/or manufacturing plants, or for the security-related monitoring of rooms or vehicles, such that for example the penetration of objects or persons can be detected. Also conceivable is a use for assisting visually impaired persons, for example in the form of obstacle warning. Other possible applications include ultrasound communication, for example for remote operation purposes.

1-12. (canceled)

13. A sound transducer system, comprising:
a piezoelectrically active electret material between a first electrode structure and a second electrode structure;
wherein the first electrode structure is configured from a plurality of electrode elements that are addressable independently of one another, and
wherein the first electrode structure is configured on a surface of a multilayer circuit bearer.

14. The sound transducer system of claim 13, wherein the second electrode structure includes a continuous metallization layer on the piezoelectrically active electret material.

15. The sound transducer system of claim 13, wherein the second electrode structure is covered by a protective layer.

16. The sound transducer system of claim 13, wherein the multilayer circuit bearer has at least one via, a via being assigned to an electrode element, and wherein the electrode element is contacted by the via to a printed conductor of an inner conductor level of the multilayer circuit bearer.

17. The sound transducer system of claim 16, wherein a plurality of printed conductors are configured on different conductor levels of the multilayer circuit bearer.

18. The sound transducer system of claim 13, wherein the piezoelectrically active electret material includes a foil.

19. The sound transducer system of claim 18, wherein the piezoelectrically active electret material is configured from two or more layers of a foil.

20. The sound transducer system of claim 13, wherein electronic components are situated on a surface of the multilayer circuit bearer situated opposite the surface.

21. The sound transducer system of claim 13, wherein the electrode elements of the first electrode structure are configured in a line.

22. The sound transducer system of claim 13, wherein the electrode elements of the first electrode structure are situated so as to be distributed two-dimensionally.

23. The sound transducer system of claim 13, wherein the multilayer circuit bearer is configured as a curved circuit board.

24. A sound wave-based sensor for environmental detection, comprising:
a sound transducer system, comprising:
a piezoelectrically active electret material between a first electrode structure and a second electrode structure;
wherein the first electrode structure is configured from a plurality of electrode elements that are addressable independently of one another, and
wherein the first electrode structure is configured on a surface of a multilayer circuit bearer.

25. The sound wave-based sensor of claim 24, wherein the sensor includes an ultrasound sensor for automotive or robotics applications.

26. The sound transducer system of claim 13, wherein the second electrode structure is covered by a multilayer protective layer.

27. The sound transducer system of claim 13, wherein the piezoelectrically active electret material includes a ferroelectret foil.
